(19) United States
(12) Patent Application Publication
(10) Pub. No.: US 2026/0032976 A1
(43) Pub. Date: Jan. 29, 2026

(54) GATE-ALL-AROUND DEVICES

(71) Applicant: Taiwan Semiconductor Manufacturing Company, Ltd., Hsinchu (TW)

(72) Inventors: Bwo-Ning Chen, Keelung City (TW); Nan-Yuan Teng, Hsinchu City (TW); Chang-Miao Liu, Hsinchu City (TW)

(21) Appl. No.: 18/785,538

(22) Filed: Jul. 26, 2024

(51) Int. Cl. H01L 29/66; H01L 29/06; H01L 29/423; H01L 29/775; H01L 29/786

(52) U.S. Cl. CPC H10D 64/015; H10D 30/014; H10D 62/116; H10D 64/017; H10D 30/43; H10D 30/6735; H10D 30/6757; H10D 62/121

(57) ABSTRACT

A method of the present disclosure includes forming over a substrate a stack having channel layers interleaved by sacrificial layers, patterning the stack and the substrate to form a fin-shaped structure, forming a dummy gate stack, depositing a gate spacer layer over the dummy gate stack, recessing a source/drain region of the fin-shaped structure to form a source/drain trench, releasing the channel layers as channel members, depositing a dummy layer over the channel members, recessing the dummy layer to form inner spacer recesses and a bottom dummy feature over a bottom surface of the source/drain trench, forming inner spacer features in the inner spacer recesses, forming a bottom isolation layer over the bottom dummy feature, forming a source/drain feature over the bottom dummy feature, removing the dummy gate stack, removing the dummy layer, and forming a gate structure to wrap around each of the channel members.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-27 illustrate fragmentary cross-sectional views of a work-in-progress (WIP) structure during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure is generally related to GAA transistors and fabrication methods thereof. GAA transistors may be fabricated using a replacement gate process, where a dummy gate stack is formed first as a placeholder and is subsequently replaced with a functional gate structure. In some replacement gate processes, sacrificial materials among nanostructures of the GAA transistor are removed after epitaxial source/drain features are formed. During the removal of the sacrificial materials, inner spacer features function to contain the etching process to define a profile of the gate structure and to protect the epitaxial source/drain features from being etched. When etching selectivity between the inner spacer features and the sacrificial materials is less than satisfactory, the profile of the gate structure may be inconsistent and the epitaxial source/drain features may be damaged.

The present disclosure provides methods for forming a GAA transistor. In an example process, a fin-shaped structure with channel layers and sacrificial layers is formed over a substrate. After formation of a dummy gate stack over a channel region of the fin-shaped structure, at least one gate spacer is formed over the dummy gate stack. Source/drain regions of the fin-shaped structure recessed. The sacrificial layers are selectively removed to release the channel layers as channel members. A dielectric dummy layer is then deposited to wrap around each of the channel members. The dielectric dummy layer is then selectively and partially recessed to form inner spacer recesses between the plurality of channel members. A first inner spacer layer and a second inner spacer layer are sequentially deposited over the inner spacer recesses. The first inner spacer layer may include aluminum oxide, polyethylene, polypropylene, or a boron-containing dielectric layer. The second inner spacer may include silicon carbonitride, silicon oxycarbonitride, silicon nitride, silicon oxycarbide, or silicon oxynitride. The deposited first inner spacer layer and second inner spacer layer are etched back to form inner spacer features. The etch back may etch the first inner spacer layer faster than it etches the second inner spacer layer such that the second inner spacer layer protrudes toward the source/drain recesses. Source/drain features are then formed over the source/drain recesses. After selective removal of the dummy gate stack, the dummy layer is selectively removed to release the channel members again. A gate structure is then formed to wrap around each of the channel members. A composition of the first inner spacer layer is selected such that it is not substantially etched when the dummy layer is etched away.

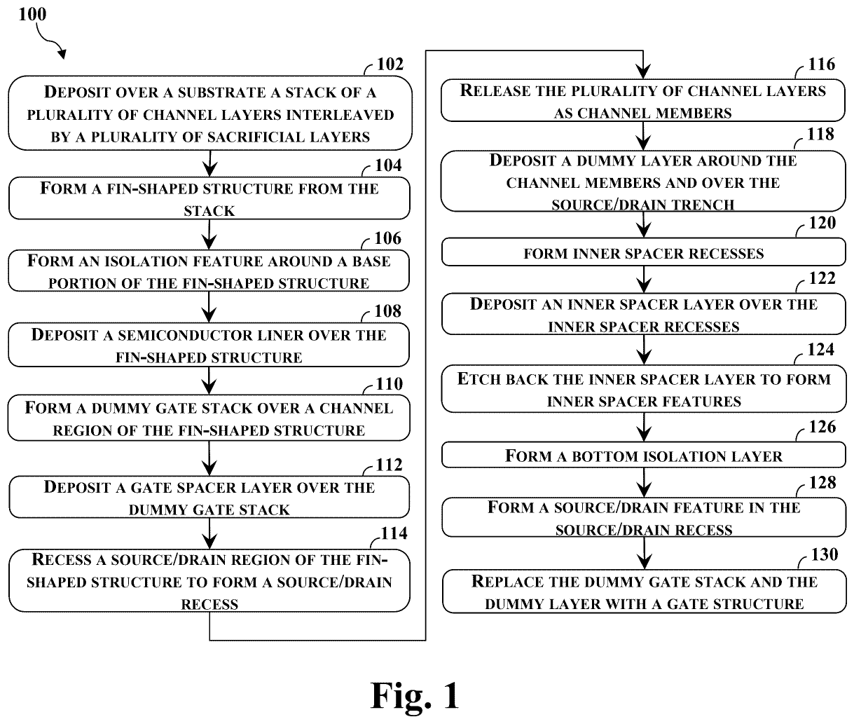

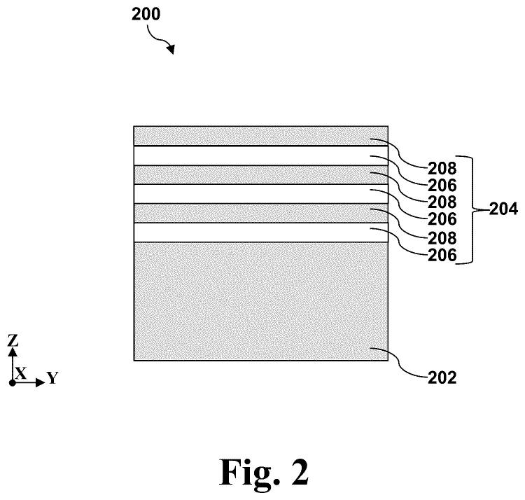

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-26, which are fragmentary cross-sectional views of a WIP structure 200 at different stages of fabrication according to embodiments of the method 100 in FIG. 1. Because the WIP structure 200 will be fabricated into a semiconductor structure or a semiconductor device, the WIP structure 200 may be referred to herein as a semiconductor structure 200 or a semiconductor device 200 as the context requires. For avoidance of doubts, the X, Y and Z directions in FIGS. 2-26 are perpendicular to one another. Throughout the present disclosure, unless expressly described otherwise, like reference numerals denote like features or steps.

Referring to FIGS. 1 and 2, method 100 includes a block 102 where a stack 204 of alternating semiconductor layers is formed over the WIP structure 200. As shown in FIG. 2, the WIP structure 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

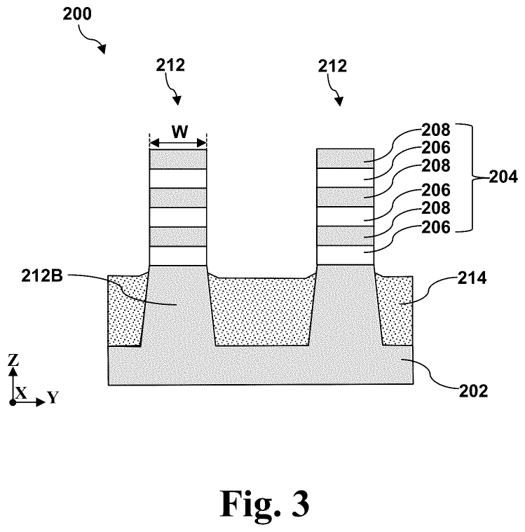

Referring to FIGS. 1 and 3, method 100 includes a block 104 where a fin-shaped structure 212 is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202 and the patterned stack 204 disposed directly over the base fin structure 212B. Each of the fin-shaped structures 212 includes a width W along the Y direction. In some instances, the width W may be between about 3 nm and about 20 nm.

Referring to FIGS. 1 and 3, method 100 includes a block 106 where an isolation feature 214 is formed around a base fin structure 212B of the fin-shaped structures 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214.

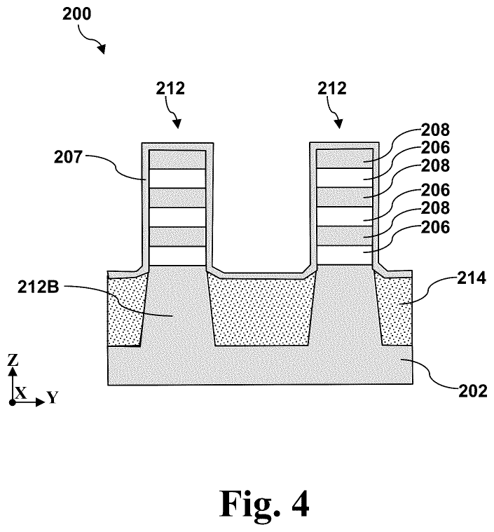

Referring to FIGS. 1 and 4, method 100 includes a block 108 where a semiconductor liner 207 is deposited over the fin-shaped structure 212. After the formation of the isolation feature 214, a semiconductor liner 207 may be deposited over the WIP structure 200, including over the isolation feature 214, over a top surface of the fin-shaped structure 212, and along sidewalls of the fin-shaped structure 212. The semiconductor liner 207 functions to protect the sidewalls of the sacrificial layers 206 as they can sustain undesirable damages during the fabrication processes. In some embodiments, the semiconductor liner 207 may include silicon (Si). In some implementations, the semiconductor liner 207 may be deposited using PVD, CVD, or atomic layer deposition (ALD).

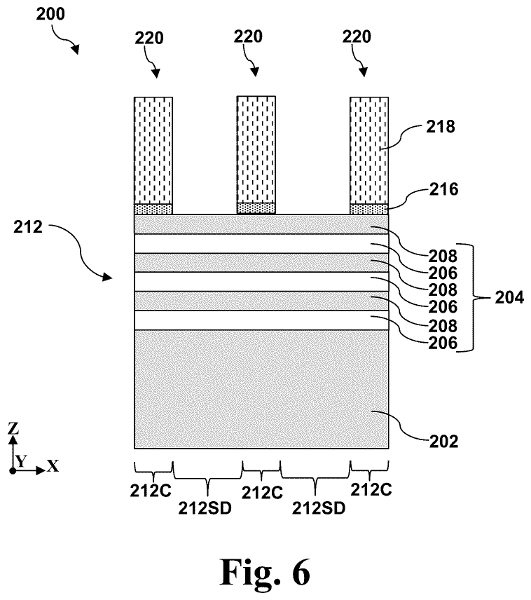

Referring to FIGS. 1, 5 and 6, method 100 includes a block 110 where a dummy gate stack 220 is formed over a channel region 212C of the fin-shaped structure 212. The dummy gate stack 220 serves as a placeholder to undergo various processes and is to be removed and replaced by a functional gate structure. Other processes and configuration are possible. In some embodiments illustrated in FIG. 6, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 6, the channel region 212C is disposed between two source/drain regions 212SD along the X direction.

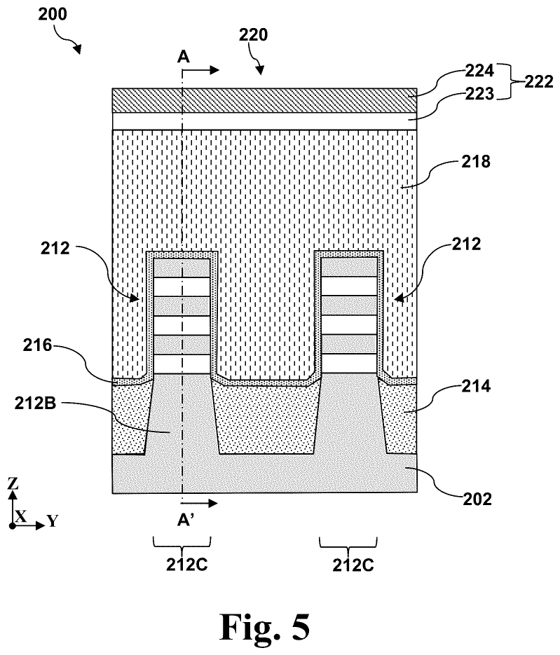

The formation of the dummy gate stack 220 may include deposition of layers in the dummy gate stack 220 and patterning of these layers. Referring to FIG. 5, a dummy dielectric layer 216, a dummy electrode layer 218, and a gate-top hard mask layer 222 may be blanketly deposited over the WIP structure 200. The dummy dielectric layer 216 may be formed on the fin-shaped structure 212 using a chemical vapor deposition (CVD) process, an ALD process, an oxygen plasma oxidation process, or other suitable processes. In the depicted embodiment, the dummy dielectric layer 216 is formed using an oxygen plasma oxidation process that substantially oxidizes the semiconductor liner 207 to form the dummy dielectric layer 216. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 6. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 6, the dummy gate stack 220 is patterned such that it is only disposed over the channel region 212C, not disposed over the source/drain region 212SD.

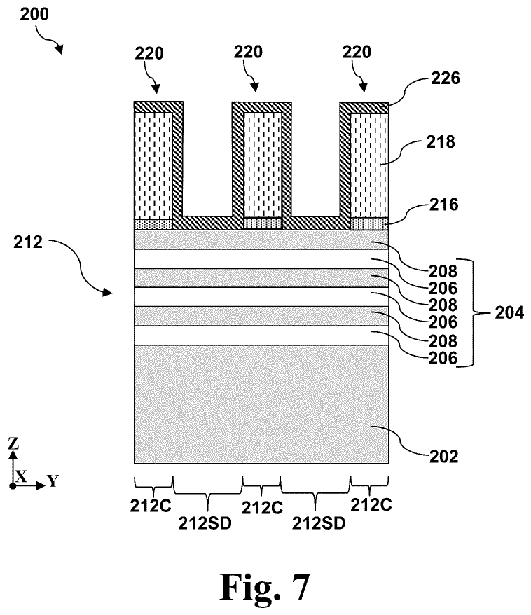

Referring to FIGS. 1 and 7, method 100 includes a block 112 where a gate spacer layer 226 is deposited over the WIP structure 200, including over the dummy gate stack 220. In some embodiments, the gate spacer layer 226 is deposited conformally over the WIP structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

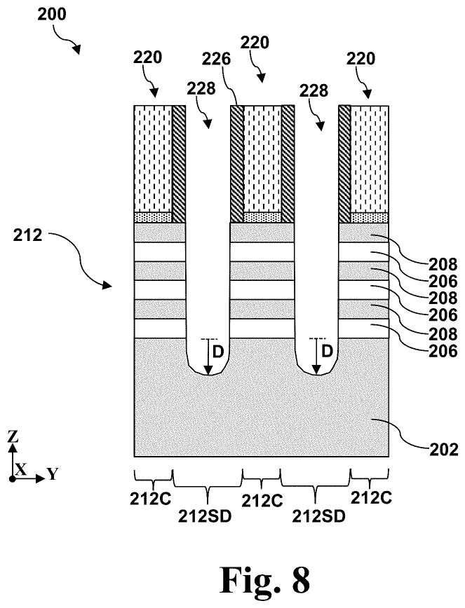

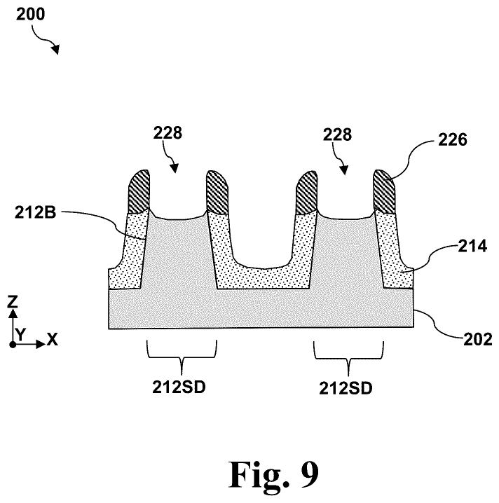

Referring to FIGS. 1, 8 and 9, method 100 includes a block 114 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202. The resulting source/drain trench 228 extends vertically through the depth of the stack 204 and partially into the substrate 202. An example dry etch process for block 114 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 8, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202. Reference is made to FIG. 9, which includes a fragmentary cross-sectional view across two adjacent source/drain regions 212SD. As shown in FIG. 9, over the source/drain regions 212SD, the majority of the fin-shaped structure 212 is etched away and a top surface of the base fin structure 212B is exposed in the source/drain region 212SD. Because the gate spacer layer 226 etches at a slower rate than the fin-shaped structure 212, the gate spacer layer 226 in the source/drain region 212SD rises above the top surface of the base fin structure 212B.

Reference is made to FIG. 8. The source/drain trench 228 extends into the substrate 202 by a depth D. In some embodiments, a ratio of the depth D of the source/drain trench 228 to the width W of the fin-shaped structure 212 may be between 0.05 and 2. This ratio is not trivial. As will be described below, a dummy layer 230 is going to be deposited and etched back in subsequent steps and it is intended for a portion of the dummy layer 230 to remain at the bottom of the source/drain trench 228. When the ratio of the depth D to the width W is below 1, it is likely that all or a substantial portion of the dummy layer 230 is going to be removed at the bottom of the source/drain trench 228. When the ratio of the depth D to the width W is greater than 1.5, the higher aspect ratio may lead to void formation in the dummy layer 230 near the bottom of the source/drain trench 228. When voids are present in the dummy layer 230 in some areas, the subsequent etching back of the dummy layer 230 may lead to inconsistent leftover dummy layer 230 at the bottom of the source/drain trench 228. The inconsistent depth of the dummy layer 230 across a wafer may introduce a number of process variations down the line and can substantially impact the process yield.

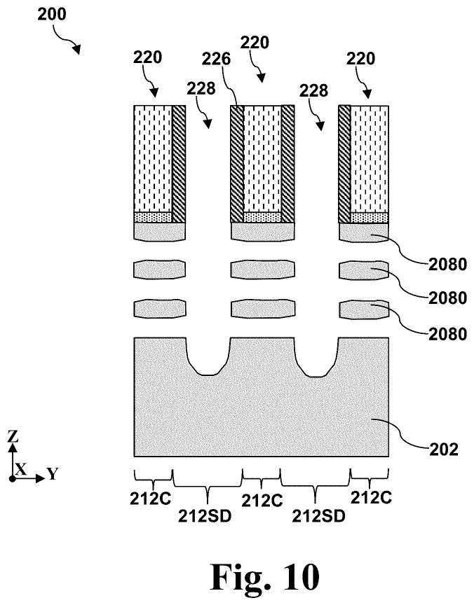

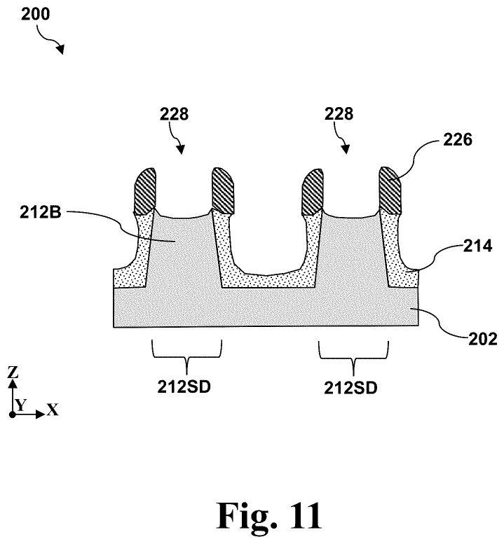

Referring to FIGS. 1, 10 and 11, method 100 includes a block 116 where the plurality of channel layers 208 in the channel regions are released as channel members 2080. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 8) to form channel members 2080 shown in FIG. 10. The selective removal of the sacrificial layers 206 forms spaces between and around adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Referring to FIG. 11. at block 116, the base fin structures 212B in the source/drain regions 212SD are not substantially etched.

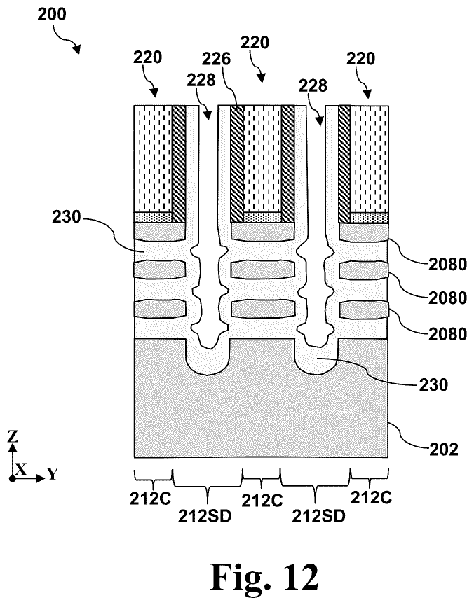

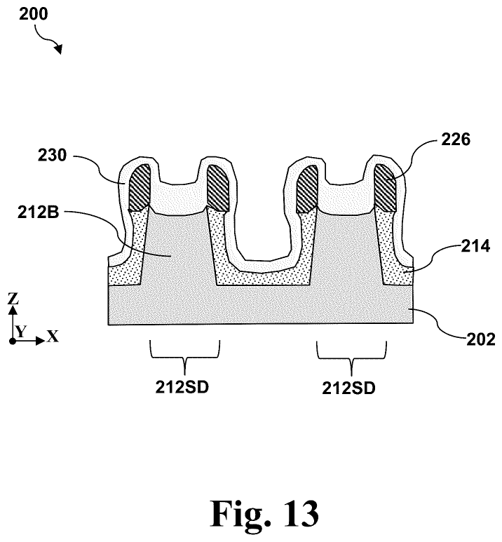

Referring to FIGS. 1, 12 and 13, method 100 includes a block 118 where a dummy layer 230 is deposited around the channel members 2080 and over the source/drain trenches 228. The dummy layer 230 may include silicon oxide and may be deposited using plasma enhanced chemical vapor deposition (PECVD) or ALD. As shown in FIG. 12, the dummy layer 230 fills the space among the channel members 2080 and covers and sidewalls of the channel members 2080. Additionally, the dummy layer 230 is in direct contact with a sidewall of the gate spacer layer 226 and a top surface of the substrate 202. Reference is made to FIG. 13, which includes a fragmentary cross-sectional view across two adjacent source/drain regions 212SD. As shown in FIG. 13, the dummy layer 230 extends conformally over the isolation feature 214, sidewalls of the gate spacer layer 226, and top surfaces of the gate spacer layer 226. Depending on the design, the channel members 2080 may take form of nanowires, nanorods, nanosheets, or other nanostructures. As illustrated in FIG. 12, because the source/drain trench 228 extends into the substrate 202 by the depth D, a thickness of the dummy layer 230 at the bottom of the source/drain trench 228 is greater than a thickness of the dummy layer 230 along sidewalls of the channel members 2080. This ensures that sufficient dummy layer 230 remains at the bottom of the source/drain trench 228 after the dummy layer 230 is etched back

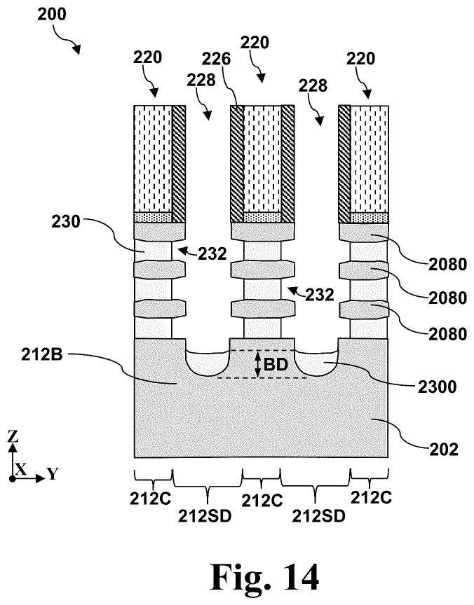

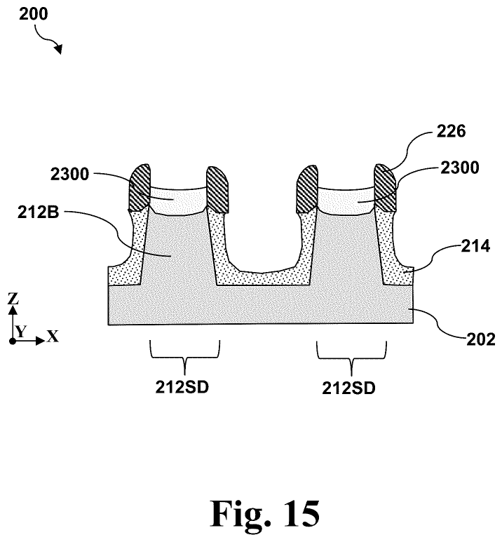

Referring to FIGS. 1, 14 and 15, method 100 includes a block 120 where inner spacer recesses 232 are formed. Referring to FIG. 14, the dummy layers 230 are selectively and partially recessed to form inner spacer recesses 232 while the gate spacer layer 226, the dummy gate stack 220, the exposed portion of the substrate 202, and the channel layers 208 are substantially unetched. In an embodiment where the channel layers 208 consist essentially of silicon (Si) and the dummy layers 230 are formed of silicon oxide, the selective recess of the dummy layer 230 may be performed using a selective wet etch process or a selective dry etch process. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. As shown in FIGS. 14 and 15, because the source/drain trench 228 extends into the substrate 202 by the depth D and the depth D is about 1 to 1.5 times of the width W, a portion of the dummy layer 230 remains at the bottom of the source/drain trench 228 to form a bottom dummy feature 2300. The bottom dummy feature 2300 includes a thickness BD. In some instances, the thickness BD of the bottom dummy feature 2300 is between about 5 nm and about 15 nm.

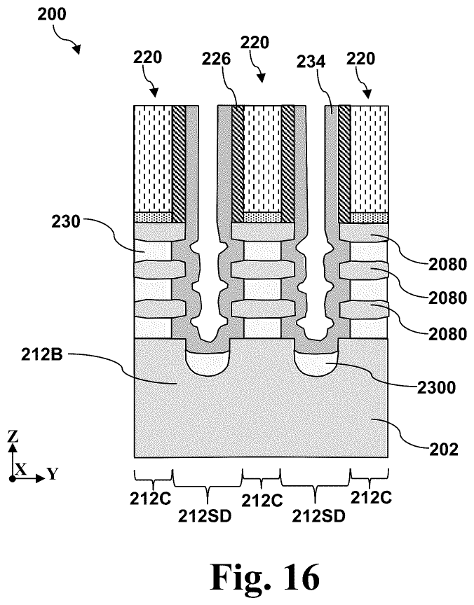

Referring to FIGS. 1 and 16, method 100 includes a block 122 where an inner spacer layer 234 is deposited over the inner spacer recesses 232. A composition of the inner spacer layer 234 is different from a composition of the dummy layer 230 to ensure that each one of them may be selectively etched without substantially damaging the other one. In some embodiments, the inner spacer layer 234 may include silicon carbonitride (SiCN), silicon oxycarbonitride (SiOCN), silicon nitride (SiN), silicon oxycarbide (SiOC), or silicon oxynitride (SiON). In some implementations, the inner spacer layer 234 may be deposited using CVD or ALD.

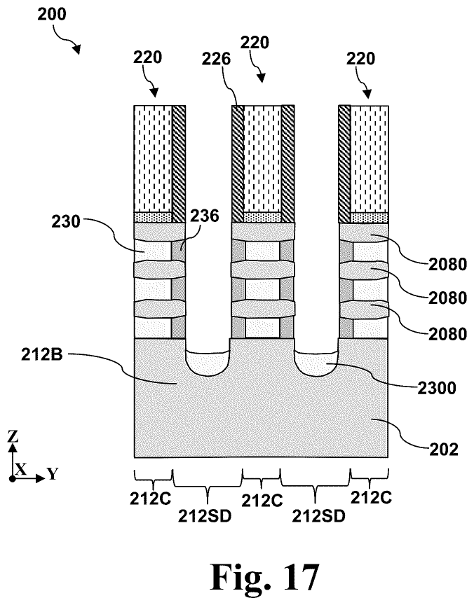

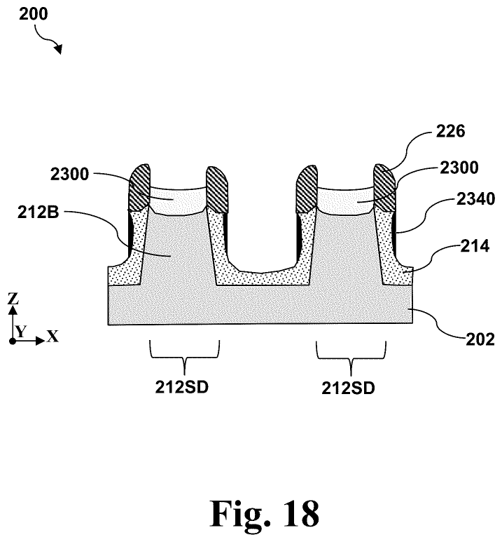

Referring to FIGS. 1, 17 and 18, method 100 includes a block 124 where the inner spacer layer 234 is etched back to form inner spacer features 236 over the inner spacer recesses 232. In some embodiments, the etching back at block 124 may include use of a dry etch process, such as a reactive ion etching (RIE) process that is aided by plasma. An example dry etch process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In embodiments depicted in FIGS. 17 and 18, the etch back at block 124 completely removes the inner spacer layer 234 over the bottom dummy feature 2300. As shown in FIG. 18, the etch back may not completely remove a sidewall portion 2340 of the first inner spacer layer 234 along sidewalls of the isolation feature 214.

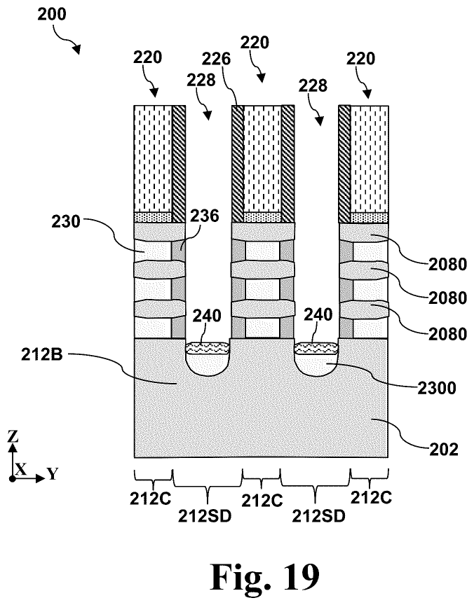

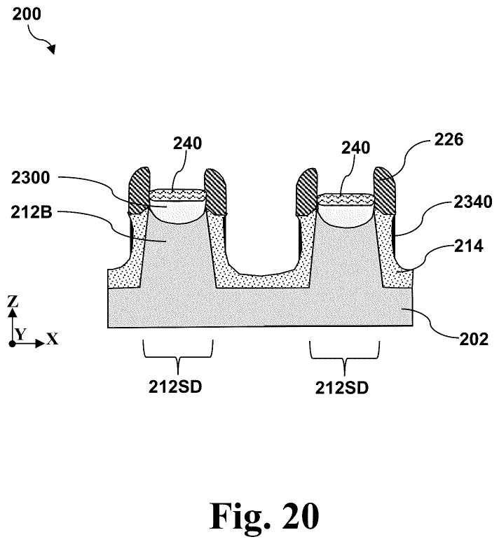

Referring to FIGS. 1, 19 and 20, method 100 includes a block 126 where a bottom isolation layer 240 is formed over the bottom dummy feature 2300. Because the bottom isolation layer 240 may interface source/drain features and oxygen content may oxidize source/drain features, the bottom isolation layer 240 may be formed of an oxygen-free dielectric material, such as silicon nitride. In an example process, a chlorine-containing silicon nitride layer is deposited over the source/drain trench 228, including over a top surface of the bottom dummy feature 2300. The chlorine-containing silicon nitride layer may be deposited using ammonia (NH₃) and a chlorine-containing silicon precursor, such as silicon tetrachloride (SiCl₄), dichlorodisilane (Si₂H₄Cl₂), dichlorosilane (SiH₂Cl₂), or hexachlorodisilane (Si₂Cl₆). The chlorine-containing silicon nitride layer may be deposited using plasma-enhanced atomic layer deposition (PEALD) or thermal ALD. A directional plasma treatment process is then performed to remove chlorine from a bottom portion of the chlorine-containing silicon nitride layer. In some embodiments, the directional plasma treatment may include use of an argon (Ar) plasma, a nitrogen (N₂) plasma, and/or a hydrogen (H₂) plasma. After the directional plasma treatment, a dry etch process using fluorine-containing etchant (e.g., trifluoromethane (CHF₃), nitrogen trifluoride (NF₃), hydrogen (H₂), ammonia (NH₃), carbon tetrafluoride (CF₄), or sulfur hexafluoride (SF₆)) may be performed. Because the dry etch process etches the chlorine-containing silicon nitride along sidewalls faster than it does relatively chlorine-free silicon nitride layer at the bottom of the source/drain trench 228, the bottom isolation layer 240 may be formed over the bottom dummy feature 2300, as shown in FIGS. 19 and 20. In some embodiments, a wet etch or a wet clean process is performed after the dry etch process to remove oxide or contamination from sidewall surfaces of the channel members 2080. In some examples, the wet etch or wet clean process may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid.

Referring to FIGS. 1, 21 and 22, method 100 includes a block 128 where a source/drain feature 244 is formed over the source/drain region 212SD. The source/drain feature 244 may be n-type or p-type. When the source/drain feature 244 is n-type, the source/drain feature 244 may include silicon (Si) and an n-type dopant, such as phosphorus (P), arsenic (As), antimony (Sb), or a combination thereof. When the source/drain feature 244 is p-type, the source/drain feature 244 may include silicon germanium (SiGe) and a p-type dopant, such as boron (B), boron difluoride (BF₂), or a combination thereof. While not explicitly shown in the figures, in some embodiments, the source/drain feature 244 may include multiple layers. For example, the source/drain feature 244 may include a lightly doped epitaxial feature over the bottom isolation layer 240 and a heavily doped epitaxial feature over the lightly doped epitaxial feature. The lightly doped epitaxial feature includes smaller dopant concentration and impurity concentration to reduce crystalline defects. The heavily doped epitaxial feature accounts for a majority of the volume to reduce contact resistance. The source/drain feature 244 may be formed using vapor-phase epitaxy (VPE), ultra-high vacuum CVD (UHV-CVD), or molecular beam epitaxy (MBE). Doping of the source/drain features 244 may be achieved with in-situ doping.

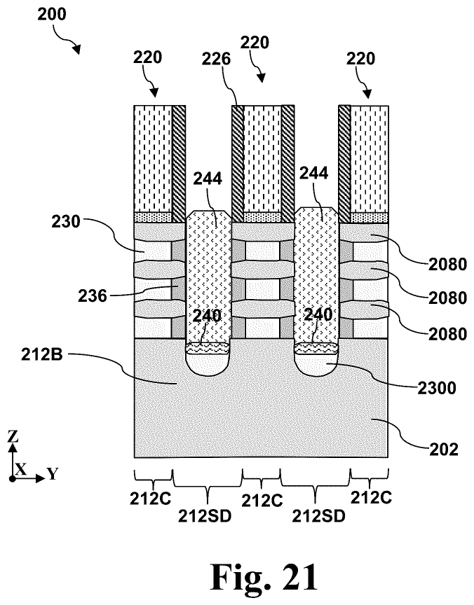

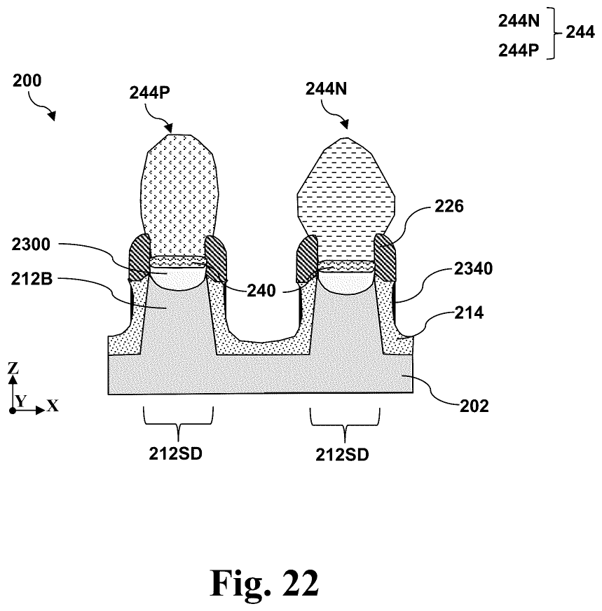

Reference is made to FIG. 22, which includes a fragmentary cross-sectional view across two adjacent source/drain regions 212SD. In some embodiments represented in FIG. 22, an n-type source/drain feature 244N may be adjacent a p-type source/drain feature 244P. The n-type source/drain feature 244N may include silicon (Si) and an n-type dopant, such as phosphorus (P), arsenic (As), or antimony (Sb). The p-type source/drain feature 244P may include silicon germanium (SiGe) and a p-type dopant, such as boron (B). Each of the n-type source/drain feature 244N and the p-type source/drain feature 244P may be in direct contact with a top surface the bottom isolation layer 240. For case of illustration and description, the n-type source/drain feature 244N and the p-type source/drain feature 244P may be collectively referred to as the source/drain feature 244, as in FIG. 21.

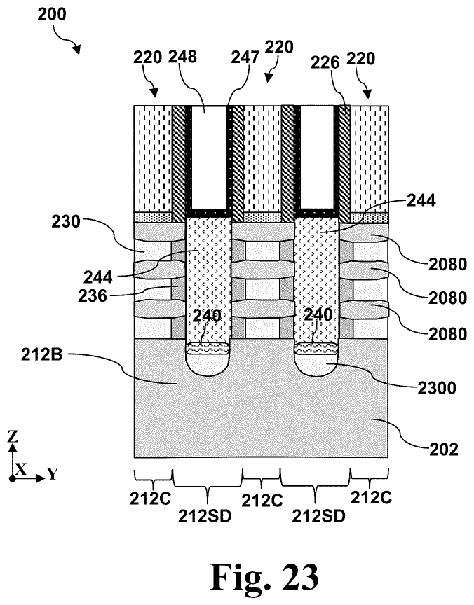

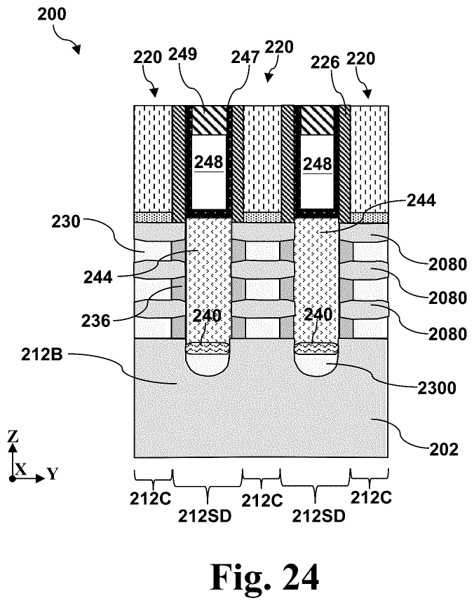

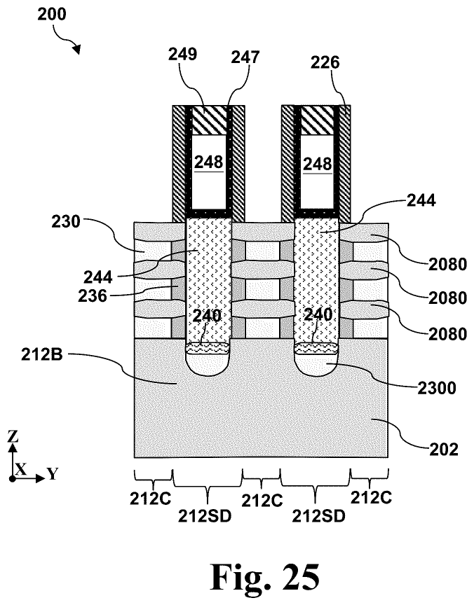

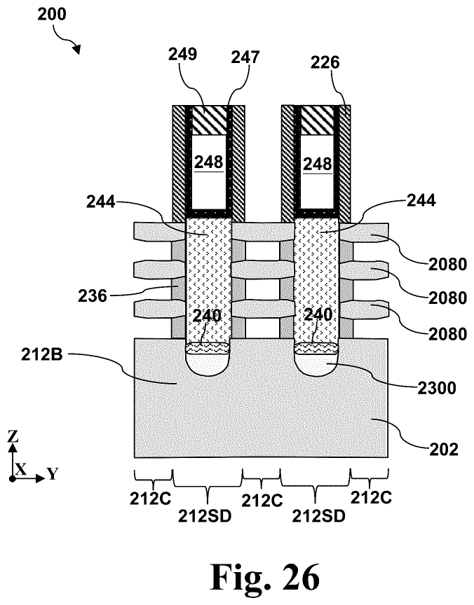

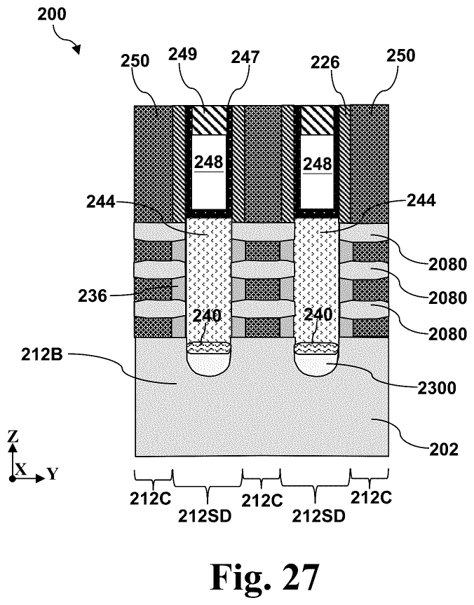

Referring to FIGS. 1 and 23-27, method 100 includes a block 130 where the dummy gate stack 220 and the dummy layer 230 are replaced with a gate structure 250. Operations at block 130 may include deposition of a contact etch stop layer (CESL) 247 over the source/drain features 244 (shown in FIG. 23), deposition of an interlayer dielectric (ILD) layer 248 over the CESL 247 (shown in FIG. 23), formation of a capping layer 249 over the ILD layer 248 (shown in FIG. 24), removal of the dummy gate stack 220 (shown in FIG. 25), removal of the dummy layer 230 (shown in FIGS. 26 and 24), and deposition of the gate structure 250 to wrap around each of the channel members 2080 (shown in FIG. 27). Referring to FIG. 23, the CESL 247 is deposited over the WIP structure 200, including over the source/drain feature 244. The CESL 247 may include silicon nitride or aluminum nitride. In some implementations, the CESL 247 may be deposited using CVD or atomic layer deposition (ALD). The ILD layer 248 is then deposited over the CESL 247. In some embodiments, the ILD layer 248 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. After the deposition of the ILD layer 248, the WIP structure 200 may be planarized by a planarization process to expose the dummy gate stack 220. For example, the planarization process may include a chemical mechanical planarization (CMP) process. In order to protect the ILD layer 248 from being damaged during the dummy layer 230 removal step, the ILD layer 248 is selectively recessed to form a top recess and a capping layer 249 is formed over the top recess. The capping layer 249 is formed of a different material than the dummy layer 230. When the dummy layer 230 includes silicon oxide, the capping layer 249 is not formed of silicon oxide so as to ensure etching selectivity. In some embodiments, the capping layer 249 may include silicon nitride, silicon carbonitride, silicon carbide, or silicon oxycarbonitride. In one embodiment, the capping layer 249 may include silicon nitride. Another planarization is performed to remove excess capping layer 249 and to expose the dummy gate stack 220. After the planarization, top surfaces of the capping layer 249, the CESL 247, the gate spacer layer 226, and the dummy gate stacks 220 are coplanar. Exposure of the dummy gate stack 220 allows the removal thereof. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220.

After the removal of the dummy gate stack 220, the dummy layer 230 in the channel region 212C is exposed, as shown in FIG. 25. A separate etch process may be performed to selectively remove the dummy layer 230 in the channel region 212C. For example, a selective wet etch process or a selective dry etch process may be performed to remove the dummy layer 230. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. By design, the selective etch of the dummy layer 230 etches the inner spacer features 236 and the bottom isolation layer 240 at a smaller rate. After the selective removal of the dummy layer 230, the channel members 2080 in the channel region 212C are once again exposed as shown in FIG. 26.

After the release of the channel members 2080, the gate structure 250 is formed to wrap around each of the channel members 2080 as shown in FIG. 27. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO2), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure 250 includes portions that interpose between channel members 2080 in the channel region 212C. In some embodiments, the gate structure 250 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

In one exemplary aspect, the present disclosure is directed to a method. The method includes forming over a substrate a stack that includes a plurality of channel layers interleaved by a plurality of sacrificial layers, patterning the stack and the substrate to form a fin-shaped structure having a base portion formed from the substrate and a stack portion formed from the stack, forming a dummy gate stack over a channel region of the fin-shaped structure, recessing a source/drain region of the fin-shaped structure to form a source/drain trench extending into the base portion, selectively removing the plurality of sacrificial layers in the channel region to release the plurality of channel layers as a plurality of channel members, depositing a dummy layer over the plurality of channel members, selectively and partially recessing the dummy layer to form inner spacer recesses among the plurality of channel members and a bottom dummy feature over a bottom surface of the source/drain trench, depositing an inner spacer layer over the inner spacer recesses, etching back the inner spacer layer to form inner spacer features in the inner spacer recesses, forming a bottom isolation layer over the bottom dummy feature, forming a source/drain feature over the source/drain region and the bottom dummy feature, after the forming of the source/drain feature, removing the dummy gate stack, removing the dummy layer, and forming a gate structure to wrap around each of the plurality of channel members.

In some embodiments, the dummy layer includes silicon oxide. In some embodiments, the bottom isolation layer includes silicon nitride. In some embodiments, the forming of the bottom isolation layer includes conformably depositing a chlorine-containing dielectric layer over the source/drain trench, anisotropically treating the chlorine-containing dielectric layer near a bottom surface of the source/drain trench, and selectively removing untreated portion of the chlorine-containing dielectric layer along sidewalls of the source/drain trench. In some implementations, the anisotropically treating includes use of argon plasma, nitrogen plasma or hydrogen plasma. In some instances, the method further includes depositing a contact etch stop layer (CESL) over the source/drain feature, depositing an interlayer dielectric (ILD) layer over the CESL, selectively recessing the ILD layer to form a top recess, and depositing a capping layer over the top recess. In some embodiments, a composition of the capping layer is different from a composition of the dummy layer. In some instances, the inner spacer layer includes silicon carbonitride, silicon oxycarbonitride, silicon nitride, silicon oxycarbide, or silicon oxynitride.

In another exemplary aspect, the present disclosure is directed to a method. The method includes forming over a substrate a stack that includes a plurality of silicon layers interleaved by a plurality of silicon germanium layers, patterning the stack and the substrate to form a fin-shaped structure having a base portion formed from the substrate and a stack portion formed from the stack, forming a dummy gate stack over a channel region of the fin-shaped structure, depositing a gate spacer layer over the dummy gate stack, after the depositing of the gate spacer layer, recessing a source/drain region of the fin-shaped structure to form a source/drain trench extending into the base portion, selectively removing the plurality of silicon germanium layers in the channel region to release the plurality of silicon layers as a plurality of channel members, depositing a semiconductor oxide layer over the plurality of channel members, selectively and partially recessing the semiconductor oxide layer to form inner spacer recesses among the plurality of channel members and a bottom feature over a bottom surface of the source/drain trench, depositing an inner spacer layer over the inner spacer recesses, etching back the inner spacer layer to form inner spacer features in the inner spacer recesses, forming a bottom isolation layer over the bottom feature, forming a source/drain feature over the source/drain region, removing the dummy gate stack, removing the semiconductor oxide layer, and forming a gate structure to wrap around each of the plurality of channel members.

In some embodiments, the method further includes depositing a contact etch stop layer (CESL) over the source/drain feature, depositing an interlayer dielectric (ILD) layer over the CESL, planarizing the ILD and CESL to expose top surfaces of the gate spacer layer, after the planarizing, selectively recessing the ILD layer to form a top recess; and depositing a capping layer over the top recess. In some embodiments, the capping layer is in contact with a top surface of the ILD layer and sidewalls of the CESL. In some implementations, the method further includes planarizing the capping layer such that top surfaces of the capping layer, the CESL, the gate spacer layer, and dummy gate stack are coplanar. In some embodiments, the capping layer includes silicon nitride. In some embodiments, the etching back of the inner spacer layer completely removes the inner spacer layer over the bottom feature.

In yet another exemplary aspect, the present disclosure is directed to a semiconductor structure. The semiconductor structure includes a base fin structure, a plurality of nanostructures over the base fin structure, a source/drain feature disposed over the base fin structure and interfacing a sidewall of each of the plurality of nanostructures, a bottom dielectric layer disposed between a bottom surface of the source/drain feature and the base fin structure, and a bottom isolation layer sandwiched between the bottom surface of the source/drain feature and the bottom dielectric layer.

In some embodiments, a composition of the bottom dielectric layer is different from a composition of the bottom isolation layer. In some embodiments, the bottom dielectric layer includes silicon oxide and the bottom isolation layer includes an oxygen-free dielectric material. In some embodiments, wherein the bottom isolation layer includes silicon nitride. In some embodiments, bottom dielectric layer includes a thickness between about 5 nm and about 15 nm. In some embodiments, the bottom dielectric layer extends into the base fin structure.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming over a substrate a stack that includes a plurality of channel layers interleaved by a plurality of sacrificial layers;
patterning the stack and the substrate to form a fin-shaped structure having a base portion formed from the substrate and a stack portion formed from the stack;
forming a dummy gate stack over a channel region of the fin-shaped structure;
recessing a source/drain region of the fin-shaped structure to form a source/drain trench extending into the base portion;
selectively removing the plurality of sacrificial layers in the channel region to release the plurality of channel layers as a plurality of channel members;
depositing a dummy layer over the plurality of channel members;
selectively and partially recessing the dummy layer to form inner spacer recesses among the plurality of channel members and a bottom dummy feature over a bottom surface of the source/drain trench;
depositing an inner spacer layer over the inner spacer recesses;
etching back the inner spacer layer to form inner spacer features in the inner spacer recesses;
forming a bottom isolation layer over the bottom dummy feature;
forming a source/drain feature over the source/drain region and the bottom dummy feature;
after the forming of the source/drain feature, removing the dummy gate stack;
removing the dummy layer; and
forming a gate structure to wrap around each of the plurality of channel members.

2. The method of claim 1, wherein the dummy layer comprises silicon oxide.

3. The method of claim 1, wherein the bottom isolation layer comprises silicon nitride.

4. The method of claim 1, wherein the forming of the bottom isolation layer comprises:
conformably depositing a chlorine-containing dielectric layer over the source/drain trench;
anisotropically treating the chlorine-containing dielectric layer near a bottom surface of the source/drain trench; and
selectively removing untreated portion of the chlorine-containing dielectric layer along sidewalls of the source/drain trench.

5. The method of claim 4, wherein the anisotropically treating comprises use of argon plasma, nitrogen plasma or hydrogen plasma.

6. The method of claim 1, further comprising:
depositing a contact etch stop layer (CESL) over the source/drain feature;
depositing an interlayer dielectric (ILD) layer over the CESL;
selectively recessing the ILD layer to form a top recess; and
depositing a capping layer over the top recess.

7. The method of claim 6, wherein a composition of the capping layer is different from a composition of the dummy layer.

8. The method of claim 1, wherein the inner spacer layer comprises silicon carbonitride, silicon oxycarbonitride, silicon nitride, silicon oxycarbide, or silicon oxynitride.

9. A method, comprising:
forming over a substrate a stack that includes a plurality of silicon layers interleaved by a plurality of silicon germanium layers;
patterning the stack and the substrate to form a fin-shaped structure having a base portion formed from the substrate and a stack portion formed from the stack;
forming a dummy gate stack over a channel region of the fin-shaped structure;
depositing a gate spacer layer over the dummy gate stack;
after the depositing of the gate spacer layer, recessing a source/drain region of the fin-shaped structure to form a source/drain trench extending into the base portion;
selectively removing the plurality of silicon germanium layers in the channel region to release the plurality of silicon layers as a plurality of channel members;
depositing a semiconductor oxide layer over the plurality of channel members;
selectively and partially recessing the semiconductor oxide layer to form inner spacer recesses among the plurality of channel members and a bottom feature over a bottom surface of the source/drain trench;
depositing an inner spacer layer over the inner spacer recesses;
etching back the inner spacer layer to form inner spacer features in the inner spacer recesses;
forming a bottom isolation layer over the bottom feature;
forming a source/drain feature over the source/drain region;
removing the dummy gate stack;
removing the semiconductor oxide layer; and
forming a gate structure to wrap around each of the plurality of channel members.

10. The method of claim 9, further comprising:
depositing a contact etch stop layer (CESL) over the source/drain feature;
depositing an interlayer dielectric (ILD) layer over the CESL;
planarizing the ILD and CESL to expose top surfaces of the gate spacer layer;
after the planarizing, selectively recessing the ILD layer to form a top recess; and
depositing a capping layer over the top recess.

11. The method of claim 10, wherein the capping layer is in contact with a top surface of the ILD layer and sidewalls of the CESL.

12. The method of claim 10, further comprising:
planarizing the capping layer such that top surfaces of the capping layer, the CESL, the gate spacer layer, and dummy gate stack are coplanar.

13. The method of claim 10, wherein the capping layer comprises silicon nitride.

14. The method of claim 9, wherein the etching back of the inner spacer layer completely removes the inner spacer layer over the bottom feature.

15. A semiconductor device, comprising:
a base fin structure;
a plurality of nanostructures over the base fin structure;
a source/drain feature disposed over the base fin structure and interfacing a sidewall of each of the plurality of nanostructures;
a bottom dielectric layer disposed between a bottom surface of the source/drain feature and the base fin structure; and
a bottom isolation layer sandwiched between the bottom surface of the source/drain feature and the bottom dielectric layer.

16. The semiconductor device of claim 15, wherein a composition of the bottom dielectric layer is different from a composition of the bottom isolation layer.

17. The semiconductor device of claim 15,
wherein the bottom dielectric layer comprises silicon oxide,
wherein the bottom isolation layer comprises an oxygen-free dielectric material.

18. The semiconductor device of claim 17, wherein the bottom isolation layer comprises silicon nitride.

19. The semiconductor device of claim 15, wherein the bottom dielectric layer comprises a thickness between about 5 nm and about 15 nm.

20. The semiconductor device of claim 15, wherein the bottom dielectric layer extends into the base fin structure.
